(19) United States
(12) Patent Application Publication
(10) Pub. No.: US 2024/0213059 A1
(43) Pub. Date: Jun. 27, 2024

(54) SUBSTRATE PROCESSING APPARATUS AND METHOD

(71) Applicant: SEMES CO., LTD., Cheonan-si, Chungcheongnam-do (KR)

(72) Inventors: Hee Man AHN, Cheonan-si (KR); Sung Hun EOM, Cheonan-si (KR); Gyeong Won SONG, Cheonan-si (KR); Jae Seung YU, Cheonan-si (KR)

(73) Assignee: SEMES CO., LTD., Cheonan-si, Chungcheongnam-do (KR)

(21) Appl. No.: 18/524,726

(22) Filed: Nov. 30, 2023

(30) Foreign Application Priority Data
Dec. 22, 2022 (KR) 10-2022-0181967

(51) Int. Cl. H01L 21/67; G03F 7/00; H01L 21/673

(52) U.S. Cl. CPC H01L 21/67225; G03F 7/70033; H01L 21/67023; H01L 21/67098; H01L 21/6732

(57) ABSTRACT

Disclosed are a substrate processing apparatus and method in which in a heat-treatment process such as a baking process, a surrounding humidity environment may be precisely controlled based on photoresist for extreme ultraviolet (EUV) applied on the substrate. The substrate processing apparatus includes a housing having a treatment space defined therein; a support unit for supporting, thereon, a substrate received in the treatment space; and a gas supply unit configured to alternately supply a first gas and a second gas into the treatment space in response to photoresist (PR) for extreme ultraviolet (EUV) applied onto the substrate.

### CROSS-REFERENCE TO RELATED PATENT APPLICATION

This application claims the benefit of Korean Patent Application No. 10-2022-0181967, filed on Dec. 22, 2022, in the Korean Intellectual Property Office, the disclosure of which is incorporated herein in its entirety by reference.

### BACKGROUND OF THE DISCLOSURE

### 1. Field of the Disclosure

The present disclosure relates to a substrate processing apparatus and method, and more specifically, a substrate processing apparatus and method in which in a heat-treatment process such as a baking process, a surrounding humidity environment may be precisely controlled based on photoresist for extreme ultraviolet applied on the substrate.

### 2. Description of the Related Art

Generally, metallic photoresist (PR) which is generally used in an extreme ultraviolet (EUV) process absolutely requires control of a surrounding humidity environment due to presence of a ligand, unlike an organic photoresist (organic PR) used in other processes.

However, a conventional bake apparatus uses Clean Dry Air (CDA) to dry general organic photoresist. The conventional bake apparatus does not precisely control a humidity environment, and as a result, the photoresist for EUV may be easily deteriorated during a process of hardening the photoresist for EUV applied to the substrate into a liquid film, resulting in unnecessary patterns or stains.

### SUMMARY OF THE DISCLOSURE

Thus, the present disclosure is intended to solve various problems, including the problems described above. Thus, a purpose of the present disclosure is to provide a substrate processing apparatus and method in which in a heat-treatment process such as a baking process, a surrounding humidity environment may be precisely controlled based on the photoresist for EUV applied on the substrate.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means illustrated in the claims and combinations thereof.

According to a first aspect of the present disclosure, a substrate processing apparatus includes a housing having a treatment space defined therein; a support unit for supporting, thereon, a substrate received in the treatment space; and a gas supply unit configured to alternately supply a first gas and a second gas into the treatment space in response to photoresist (PR) for extreme ultraviolet (EUV) applied onto the substrate.

In one implementation of the substrate processing apparatus, the first gas is humidified air for providing a humidifying environment to the photoresist, wherein the second gas is an inert gas for providing a dehumidifying environment or a surrounding moisture blocking environment to the photoresist.

In one implementation of the substrate processing apparatus, the gas supply unit includes: a gas supply line installed in the housing so as to supply the humidified air or the inert gas; a three-way valve having an output connected to the gas supply line; a humidified air supply line connected to one input of the three-way valve; and a first inert gas supply line connected to the other input of the three-way valve.

In one implementation of the substrate processing apparatus, the substrate processing apparatus further comprises a controller configured to: apply a humidified air supply control signal for connecting the gas supply line and the humidified air supply line to each other to the three-way valve during a humidification process; and apply an inert gas supply control signal for connecting the gas supply line and the first inert gas supply line to each other to the three-way valve during a dehumidification process or when blocking surrounding moisture.

In one implementation of the substrate processing apparatus, a heater is installed in the humidified air supply line so as to prevent condensation of the humidified air.

In one implementation of the substrate processing apparatus, the housing includes: an upper housing having at least one gas spray hole defined therein for spraying the first gas or the second gas toward the substrate and a gas discharge hole defined therein for discharging the sprayed gas to an outside; a lower housing spaced apart from the upper housing so that the treatment space is defined therebetween, wherein the support unit is installed on an inner upper surface of the lower housing; and a ring shutter installed at the lower housing or the upper housing and configured to vertically move to block a space defined between the upper housing and the lower housing to seal the treatment space.

In one implementation of the substrate processing apparatus, the at least one gas spray hole includes: a vertical spray hole extending in a vertical direction toward an edge portion of the substrate; and an inclined spray hole extending inclinedly toward a center portion of the substrate.

In one implementation of the substrate processing apparatus, the gas discharge hole is formed in a center portion of the upper housing corresponding to the center portion of the substrate so that the gas flows from the edge portion of the substrate to the center portion of the substrate.

In one implementation of the substrate processing apparatus, the housing further includes a sealing member installed on a lower surface of the upper housing or an upper surface of the lower housing to prevent inflow of external air into the treatment space.

In one implementation of the substrate processing apparatus, the housing further includes a ring shutter vertically-moving unit for moving the ring shutter vertically.

In one implementation of the substrate processing apparatus, the support unit includes: a heating plate having a heater built therein to heat the substrate; a lift pin installed at the heating plate so as to pass through the heating plate and configured to vertically move the substrate in loading and unloading the substrate; and a proximity pin installed on the heating plate so as to support the substrate thereon such that the substrate is spaced from the heating plate in proximity thereto when the lift pin descends.

In one implementation of the substrate processing apparatus, the substrate processing apparatus further comprises: a heat-treatment chamber; a cooling unit installed in the heat-treatment chamber so as to cool the substrate; and a heating unit installed in the heat-treatment chamber so as to heat the substrate, wherein the heating unit includes the housing, the support unit, and the gas supply unit, wherein the heat-treatment chamber includes: a chamber body having a substrate passage defined at one side thereof; a gate valve for blocking the substrate passage; and a second inert gas supply line installed in the heat-treatment chamber so as to supply an inert gas into the heat-treatment chamber.

According to a second aspect of the present disclosure, a substrate processing method includes: (a) supplying an inert gas into a housing while the housing is an open state; (b) loading a substrate having photoresist (PR) for extreme ultraviolet (EUV) coated thereon into the housing; (c) sealing the housing; (d) supplying humidified air into the housing to create a humidifying environment on the substrate; (e) heating the substrate using a heating plate while supplying the inert gas into the housing to create a dehumidifying environment on the substrate; (f) supplying the inert gas into the housing while opening the housing; and (g) unloading the substrate out of the housing.

In one implementation of the substrate processing method, after the (e), the (d) or the (e) is repeated at least once.

In one implementation of the substrate processing method, in the (d), the humidified air flows from an edge portion of the substrate to a center portion of the substrate using a gas spray hole corresponding to the edge portion of the substrate and a gas discharge hole corresponding to the center portion of the substrate.

In one implementation of the substrate processing method, in the (e), the inert gas flows from an edge portion of the substrate to a center portion of the substrate using a gas spray hole corresponding to the edge portion of the substrate and a gas discharge hole corresponding to the center portion of the substrate.

In one implementation of the substrate processing method, in the (a), the housing is opened by lowering a ring shutter installed at a lower housing, wherein the housing includes an upper housing and the lower housing.

In one implementation of the substrate processing method, in the (c), the ring shutter installed at the lower housing is raised up toward the upper housing to seal the housing.

In one implementation of the substrate processing method, the method further comprises, before the (a), (h) supplying the inert gas into a heat-treatment chamber so as to form a shape surrounding the housing so that an inert gas environment is created around the housing.

According to a third aspect of the present disclosure, a substrate processing apparatus incudes a heat-treatment chamber; a cooling unit installed in the heat-treatment chamber so as to cool the substrate; and a heating unit installed in the heat-treatment chamber so as to heat the substrate, wherein the heating unit includes: a housing having a treatment space defined therein; a support unit for supporting, thereon, a substrate received in the treatment space; and a gas supply unit configured to alternately supply a first gas and a second gas into the treatment space in response to photoresist (PR) for extreme ultraviolet (EUV) applied onto the substrate, wherein the heat-treatment chamber includes: a chamber body having a substrate passage defined at one side thereof; a gate valve for blocking the substrate passage; and a second inert gas supply line installed in the heat-treatment chamber so as to supply an inert gas into the heat-treatment chamber, wherein the first gas is humidified air for providing a humidifying environment to the photoresist, wherein the second gas is an inert gas for providing a dehumidifying environment or a surrounding moisture blocking environment to the photoresist, wherein the gas supply unit includes: a gas supply line installed in the housing so as to supply the humidified air or the inert gas; a three-way valve having an output connected to the gas supply line; a humidified air supply line connected to one input of the three-way valve; and a first inert gas supply line connected to the other input of the three-way valve, wherein the substrate processing apparatus further comprises a controller configured to: apply a humidified air supply control signal for connecting the gas supply line and the humidified air supply line to each other to the three-way valve during a humidification process; and apply an inert gas supply control signal for connecting the gas supply line and the first inert gas supply line to each other to the three-way valve during a dehumidification process or when blocking surrounding moisture, wherein a heater is installed in the humidified air supply line so as to prevent condensation of the humidified air, wherein the housing includes: an upper housing having at least one gas spray hole defined therein for spraying the first gas or the second gas toward the substrate and a gas discharge hole defined therein for discharging the sprayed gas to an outside; a lower housing spaced apart from the upper housing so that the treatment space is defined therebetween, wherein the support unit is installed on an inner upper surface of the lower housing; and a ring shutter installed at the lower housing or the upper housing and configured to vertically move to block a space defined between the upper housing and the lower housing to seal the treatment space, wherein the at least one gas spray hole includes: a vertical spray hole extending in a vertical direction toward an edge portion of the substrate; and an inclined spray hole extending inclinedly toward a center portion of the substrate, wherein the gas discharge hole is formed in a center portion of the upper housing corresponding to the center portion of the substrate so that the gas flows from the edge portion of the substrate to the center portion of the substrate.

According to various embodiments of the present disclosure as described above, the surrounding humidity environment may be precisely controlled based on the photoresist for extreme ultraviolet applied on the substrate in a heat-treatment process such as a bake process. Repeating the humidification and dehumidification may allow a high-quality liquid film to be formed on the surface of the substrate, thereby producing a high-quality substrate. Not only in the bake process, but also in the heat-treatment process that repeats heating and cooling, the inert gas environment may be created to prevent reaction of the liquid film with external moisture, thereby producing a high-quality product.

Effects of the present disclosure are not limited to the effects mentioned above, and other effects not mentioned will be clearly understood by those skilled in the art from the descriptions below.

### BRIEF DESCRIPTION OF THE DRAWINGS

The above and other purposes, features and other advantages of the present disclosure will be more clearly understood from the following detailed description taken in conjunction with the accompanying drawings, in which:

FIG. 1 is a perspective view schematically showing a substrate processing apparatus according to some embodiments of the present disclosure;

FIG. 2 is a side elevation view showing the substrate processing apparatus in FIG. 1;

FIG. 3 is a top view of the substrate processing apparatus in FIG. 1;

FIG. 4 is a top view showing a hand of a transfer unit of the substrate processing apparatus in FIG. 3;

FIG. 5 is a top cross-sectional view schematically showing a heat-treatment chamber in FIG. 3;

FIG. 6 is a side cross-sectional view schematically showing the heat-treatment chamber in FIG. 3;

FIG. 7 is a side cross-sectional view showing a housing of the heating unit in FIG. 6 in an open state;

FIG. 8 is a side cross-sectional view showing the housing of the heating unit in FIG. 6 in a closed state;

FIG. 9 is a cutaway perspective view of the heating unit in FIG. 6; and

FIG. 10 is a flowchart showing a substrate treatment method according to some embodiments of the present disclosure.

### DETAILED DESCRIPTION OF THE DISCLOSURE

Hereinafter, various preferred embodiments of the present disclosure will be described in detail with reference to the attached drawings.

The embodiments of the present disclosure are provided to more completely describe the present disclosure for those skilled in the art. The following embodiments may be modified in various forms, and the scope of the present disclosure is not limited to the following embodiments. Rather, these embodiments are provided so that the present disclosure is thorough and complete, and are provided to fully convey the spirit of the present disclosure to those skilled in the art. Furthermore, a thickness or a size of each layer in the drawing is exaggerated for convenience and clarity of illustration. A shape, a size, a ratio, an angle, a number, etc. disclosed in the drawings for describing embodiments of the present disclosure are illustrative, and the present disclosure is not limited thereto. The same reference numerals refer to the same elements herein.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof.

Hereinafter, embodiments of the present disclosure will be described with reference to drawings schematically showing ideal embodiments of the present disclosure. In the drawings, variations of a depicted shape may be expected, depending, for example, on manufacturing techniques and/or tolerances. Therefore, the embodiments of the present disclosure should not be construed as being limited to the specific shape of the area shown herein, and should include, for example, change in a shape caused in a manufacturing process.

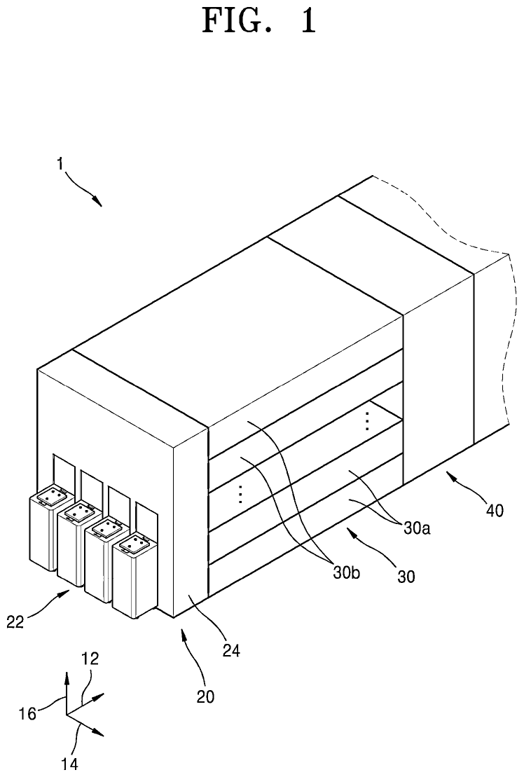

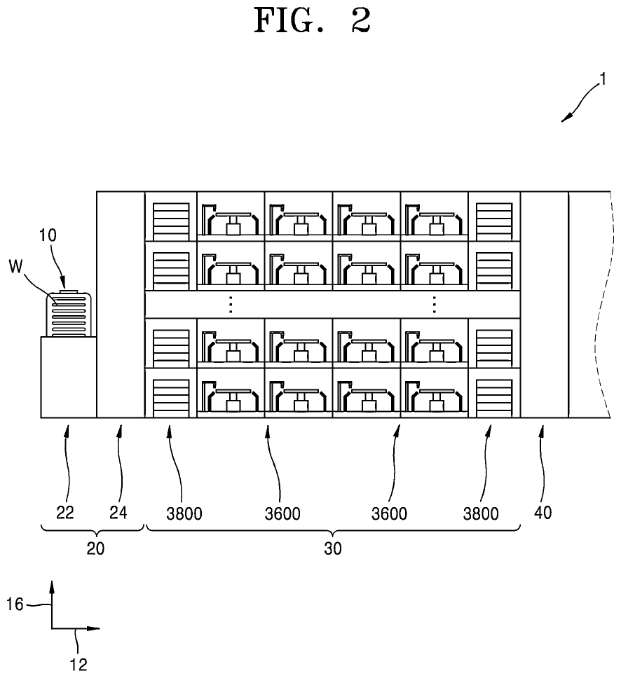

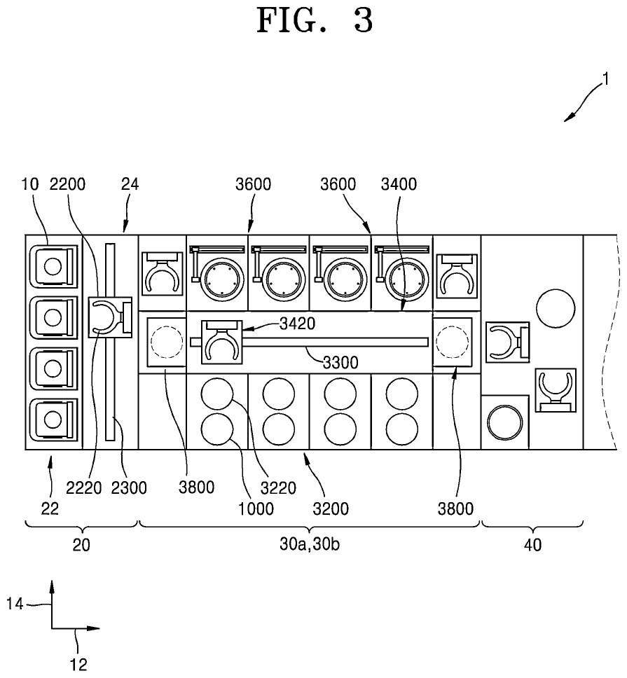

FIG. 1 is a perspective view schematically showing a substrate processing apparatus 1 according to some embodiments of the present disclosure, FIG. 2 is a side elevation view showing the substrate processing apparatus 1 in FIG. 1, and FIG. 3 is a top view showing the substrate processing apparatus 1 in FIG. 1.

As shown in FIGS. 1 to 3, the substrate processing apparatus 1 according to some embodiments of the present disclosure includes an index module 20, a treating module 30, and an interface module 40. According to one embodiment, the index module 20, the treating module 30, and the interface module 40 are sequentially arranged in a line. Hereinafter, a direction in which the index module 20, the treating module 30, and the interface module 40 are arranged is referred to as an X-axis direction 12, and a direction perpendicular to the X-axis direction 12 in a top view is a Y-axis direction 14. A Z-axis direction 16 is perpendicular to both the X-axis direction 12 and the Y-axis direction 14.

The index module 20 transfers the substrate W from a container 10 in which the substrate W is stored to the treating module 30, and stores a treated substrate W in the container 10. A length direction of the index module 20 is the Y-axis direction 14. The index module 20 has a load port 22 and an index frame 24. The load port 22 is opposite to the treating module 30 around the index frame 24. The container 10 containing the substrates W is disposed in the load port 22. A plurality of load ports 22 may be provided, and the plurality of load ports 22 may be arranged along the Y-axis direction 14.

The container 10 may be embodied as a sealed container 10 such as a front open unified pod (FOUP). The container 10 may be disposed in the load port 22 using transport means (not shown) such as an overhead transfer, an overhead conveyor, or an automatic guided vehicle (not shown) or by an operator.

An index robot 2200 is provided inside the index frame 24. Within the index frame 24, a guide rail 2300 extending in the Y-axis direction 14 as a length direction thereof is disposed. The index robot 2200 may be configured to be movable on the guide rail 2300. The index robot 2200 includes a hand 2220 on which the substrate W is placed. The hand 2220 may be configured to move forward and backward, to rotate about the Z-axis direction 16, and to be movable in the Z-axis direction 16.

The treating module 30 performs an application process and a developing process on the substrate W. The treating module 30 has an application block 30a and a developing block 30b. The application block 30a performs the application process on the substrate W, and the developing block 30b performs the developing process on the substrate W. A plurality of application blocks 30a are provided, and are stacked on top of each other. A plurality of developing blocks 30b are provided, and the developing blocks 30b are stacked on top of each other.

According to an embodiment of FIG. 1, two application blocks 30a are provided, and two developing blocks 30b are provided. The application blocks 30a may be disposed under the developing blocks 30b. In one example, the two application blocks 30a may perform the same process and may have the same structure. Furthermore, the two developing blocks 30b may perform the same process and may have the same structure. However, the present disclosure is not limited thereto.

Referring to FIG. 3, the application block 30a has a heat-treatment chamber 3200, a transfer chamber 3400, a liquid treatment chamber 3600, and a buffer chamber 3800. The heat-treatment chamber 3200 performs a heat-treatment process on the substrate W. The heat-treatment process may include a cooling process and a heating process. The liquid treatment chamber 3600 supplies liquid on the substrate W to form a liquid film. The liquid film may be a photoresist film or an antireflection film. The transfer chamber 3400 transfers the substrate W between the heat-treatment chamber 3200 and the liquid treatment chamber 3600 and within the application block 30a.

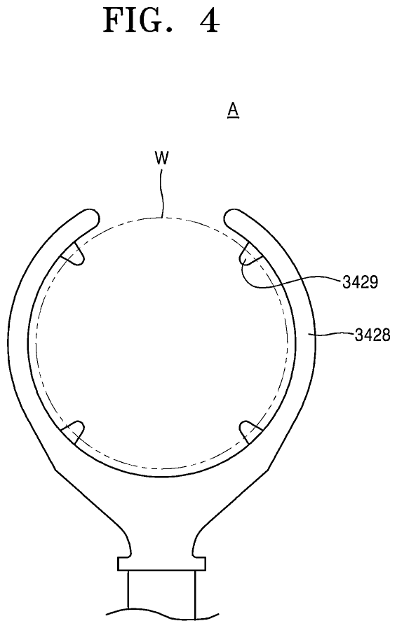

The transfer chamber 3400 has a length direction parallel to the X-axis direction 12. A transfer unit 3420 is provided in the transfer chamber 3400. The transfer unit 3420 transfers the substrate between the heat-treatment chamber 3200, the liquid treatment chamber 3600, and the buffer chamber 3800. In one example, the transfer unit 3420 has a hand A (see FIG. 4) on which the substrate W is placed, wherein the hand A may be configured to move forward and backward, rotate about the Z-axis direction 16, and be movable along the Z-axis direction 16. A guide rail 3300 whose a length direction is parallel to the X-axis direction 12 is disposed in the transfer chamber 3400. The transfer unit 3420 may be configured to be movable on the guide rail 3300.

FIG. 4 is a plan view showing the hand A of the transfer unit 3420 of the substrate processing apparatus 1 in FIG. 3.

As shown in FIG. 4, the hand A has a base 3428 and a support protrusion 3429. The base 3428 may have an annular ring shape partially cut. The base 3428 has an inner diameter larger than a diameter of the substrate W. The support protrusion 3429 extends inwardly from the base 3428.

A plurality of support protrusions 3429 are provided to support an edge area of the substrate W. In an example, four support protrusions 3429 may be arranged by an equal spacing.

Referring again to FIG. 2 and FIG. 3, a plurality of heat-treatment chambers 3200 are provided. The heat-treatment chambers 3200 are arranged in a row along the X-axis direction 12. The heat-treatment chambers 3200 are located on one side of the transfer chamber 3400.

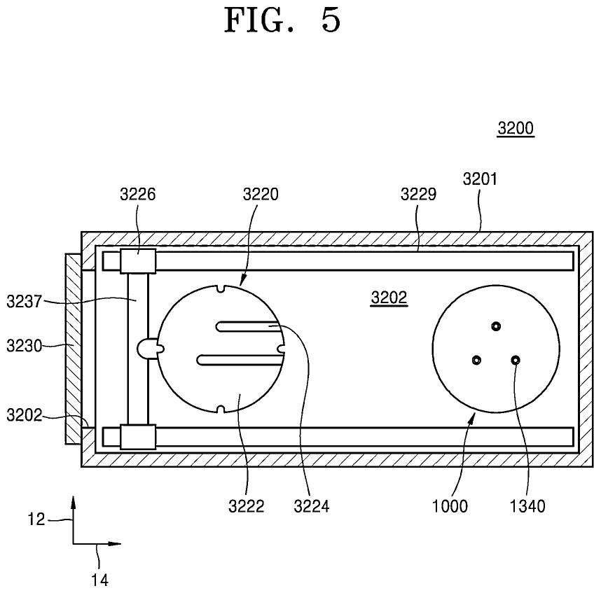

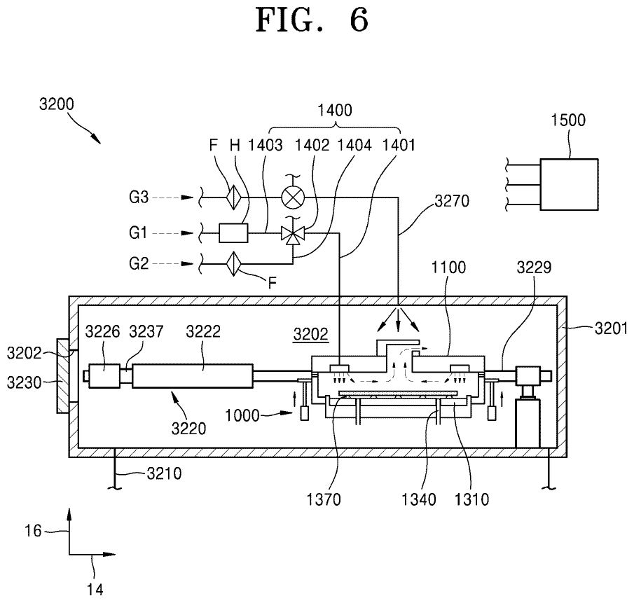

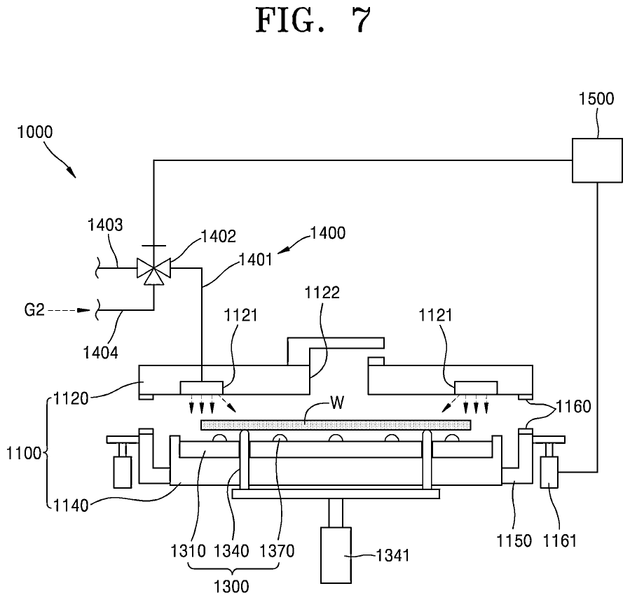

FIG. 5 is a top cross-sectional view schematically showing the heat-treatment chamber 3200 in FIG. 3. FIG. 6 is a side cross-sectional view schematically showing the heat-treatment chamber 3200 in FIG. 3. FIG. 7 is a side cross-sectional view of a heating unit 1000 in FIG. 6.

The heat-treatment chamber 3200 may include a cooling unit 3220 installed inside the heat-treatment chamber 3200 to cool the substrate W, and a heating unit 1000 installed inside the heat-treatment chamber 3200 to heat the substrate W.

The heat-treatment chamber 3200 may include a chamber body 3201 having a substrate passage 3202 formed at one side thereof and adjacent to the cooling unit 3220, a gate valve 3230 that blocks the substrate passage 3202, and a second inert gas supply line 3270 installed in the heat-treatment chamber 3200 so as to supply an inert gas such as nitrogen or argon as a third gas G3 into the heat-treatment chamber 3200.

A filter F is disposed in the second inert gas supply line 3270 to supply clean inert gas to the heat-treatment chamber 3200.

Therefore, since the second inert gas supply line 3270 is used to protect an inside of the heat-treatment chamber 3200 from surrounding moisture, deterioration, patterns, or stains of the liquid film may be prevented to obtain a high-quality liquid film.

The heating unit 1000 may include a housing 1100, a support unit 1300, and a gas supply unit 1400.

The cooling unit 3220 and the heating unit 1000 are disposed in the internal space 3202 of the treating container 3201. The cooling unit 3220 and the heating unit 1000 are arranged side by side along the Y-axis direction 14. An exhaust line 3210 may be connected to the treating container 3201. The exhaust line 3210 may exhaust gas supplied under an operation of a fan unit (not illustrated) out of the treating container 3201. The exhaust line 3210 may be connected to a bottom of the treating container 3201. However, the present disclosure is not limited thereto, and the exhaust line 3210 may be connected to a side, etc. of the treating container 3201.

The cooling unit 3220 has a cooling plate 3222. The substrate W may be disposed on the cooling plate 3222. The cooling plate 3222 may have a generally circular shape in a top view. A cooling member (not shown) is provided in the cooling plate 3222. In one example, the cooling member is formed inside the cooling plate 3222 and may be embodied as a flow path through which a cooling fluid flows. Accordingly, the cooling plate 3222 may cool the substrate W. The cooling plate 3222 may have a diameter corresponding to that of the substrate W. A notch may be formed at an edge of the cooling plate 3222. The notch may have a shape corresponding to that of the support protrusion 3429 formed on the hand A as described above. Furthermore, the number of notches may correspond to the number of the support protrusions 3429 formed on the hand A. Each notch may be positioned at a location corresponding to that of each of the support protrusions 3429. When a vertical level of each of the hand A and the cooling plate 3222 changes, the substrate W is transferred between the hand A and the cooling plate 3222.

The cooling plate 3222 has a plurality of slit-shaped guide grooves 3224 defined therein. The guide groove 3224 extends from an end of the cooling plate 3222 to an inside of the cooling plate 3222. The guide groove 3224 has a length direction along the Y-axis direction 14. The guide grooves 3224 are arranged so as to be spaced apart from each other along the X-axis direction 12. The guide groove 3224 prevents the cooling plate 3222 and a lift pin 1340 from interfering with each other when the substrate is transferred between the cooling plate 3222 and the heating unit 1000.

The cooling plate 3222 may be supported on a support member 3237. The support member 3237 may include a bar-shaped first support member and a second support member coupled to a middle of the first support member. One end and the other end of the first support member are coupled to a driver 3226. The driver 3226 is mounted on the guide rail 3229. In a top view, the guide rail 3229 has a length direction along the Y-axis direction 14 and may be provided on each of both opposing sides of the treating container 3201. The cooling plate 3222 may be movable along the Y-axis direction 14 under an operation of the driver 3226 mounted on the guide rail 3229.

The heating unit 1000 may include the housing 1100 in which the treatment space is formed, the support unit 1300 that supports, thereon, the substrate W placed in the treatment space, and a gas supply unit 1400 that alternately supplies first gas G1 and second gas G2 to the treatment space in response to the photoresist (PR) for EUV (Extreme Ultraviolet) applied onto the substrate W.

The first gas G1 may be humidified air that may provide a humidifying environment to the photoresist, and the second gas G2 may be an inert gas that may provide a dehumidifying environment or a surrounding moisture blocking environment to the photoresist.

Unlike the existing Clean Dry Air (CDA) from which moisture has been removed, the humidified air may refer to a state in which a certain portion of moisture remains without being removed, that is, may have a moisture content above a reference value. In this regard, the reference value of the moisture content may vary depending on a type of the photoresist for EUV.

The gas supply unit 1400 may include a gas supply line 1401 installed in the housing 1100 and capable of supplying the humidified air or the inert gas, a three-way valve 1402 whose an output is connected to the gas supply line 1401, a humidified air supply line 1403 connected to one input of the three-way valve 1402 and a first inert gas supply line 1404 connected to the other input of the three-way valve 1402.

A heater H may be installed in the humidified air supply line 1403 to prevent condensation of the humidified air, and a filter F may be installed in the first inert gas supply line 1404.

The heating unit 1000 may further include a controller 1500 that applies a humidified air supply control signal for connecting the gas supply line 1401 and the humidified air supply line 1403 to each other to the three-way valve 1402 during the humidification process, and applies an inert gas supply control signal for connecting the gas supply line 1401 and the first inert gas supply line 1404 to each other to the three-way valve 1402 during a dehumidification process or when blocking surrounding moisture.

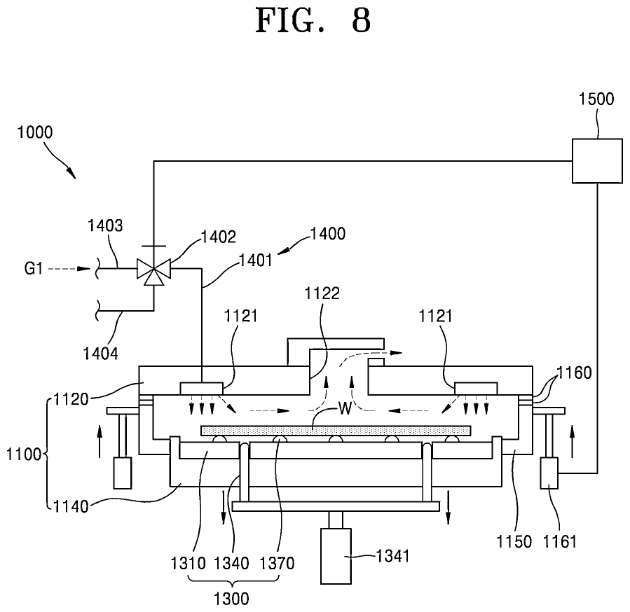

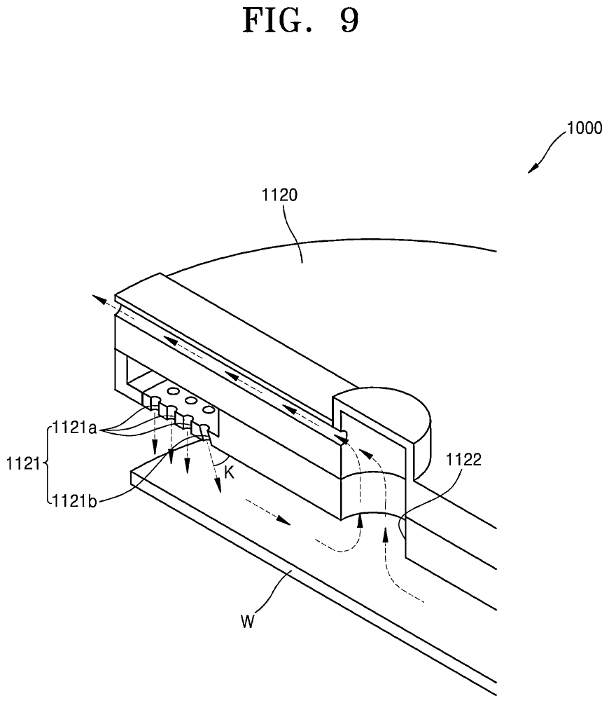

FIG. 7 is a side cross-sectional view showing the housing of the heating unit 1000 in FIG. 6 in an open state. FIG. 8 is a side cross-sectional view showing the housing of the heating unit 1000 in FIG. 6 in a closed state, and FIG. 9 is a cutaway perspective view showing the heating unit 1000 in FIG. 6.

As shown in FIG. 7 and FIG. 8, the housing 1100 may include an upper housing 1120 having at least one gas spray hole 1121 defined therein for spraying the first gas G1 or the second gas G2 toward the substrate W and a gas discharge hole 1122 defined therein for discharging the sprayed gas; a lower housing 1140 spaced apart from the upper housing 1120 so that the treatment space may be formed therebetween, wherein the support unit 1300 is installed on an inner top surface of the lower housing 1140; and a ring shutter 1150 installed at the upper housing 1120 or the lower housing 1140 so as to vertically move to seal the treatment space defined between the upper housing 1120 and the lower housing 1140.

The lower housing 1140 may be formed in a cylindrical shape with an open top. The upper housing 1120 may be formed in a circular plate shape that is spaced apart from the lower housing 1140 and faces an opening of the lower housing 1140.

Each of the upper housing 1120 and the lower housing 1140 may be fixed. The treatment space that may be opened and closed by the ring shutter 1150 may be formed therebetween.

The housing 1100 may further include a sealing member 1160 installed on a lower surface of the upper housing 1120 or an upper surface of the lower housing 1140 to prevent inflow of external air into the treatment space, and a ring shutter vertically-moving unit 1161 that moves the ring shutter 1150 vertically.

Therefore, under control by the controller 1500, the ring shutter vertically-moving unit 1161 lowers down the ring shutter 1150 to open the space between the upper housing 1120 and the lower housing 1140, or the ring shutter vertically-moving unit 1161 raises up the ring shutter 1150 to close the space between the upper housing 1120 and the lower housing 1140. At the latter case, the treatment space is sealed by the closely-contacting sealing member 1160 to protect an internal environment therein.

The support unit 1300 may include a heating plate 1310 installed in the treatment space, and having a heater (not shown) built therein to heat the substrate W; a lift pin 1340 installed at the heating plate 1310 so as to vertically move the substrate Win loading and unloading the substrate W; a lift pin driver 1341 to vertically move the lift pin 1340; and a proximity pin 1370 installed at the heating plate 1310 so as to support the substrate W such that the substrate W is spaced from the heating plate 1310 in a proximity manner thereto when the lift pin 1340 descends.

The heating plate 1310 may support the substrate W thereon in the treatment space. The substrate W may be placed on the heating plate 1310. The heating plate 1310 has a generally circular shape in a top view. The heating plate 1310 has a larger diameter than that of the substrate W.

The heating plate 1310 may have a heating wire pattern (not shown) or a heater (not shown) built therein. The heating wire pattern is a type of heater and may be embodied as a heating resistor that generates heat when an electric current is applied thereto. Accordingly, the heating plate 1310 may heat the substrate W. The lift pin 1340 may be movable up and down along the Z-axis direction 16 perpendicular to the upper surface of the heating plate 1310. The lift pin 1340 may receive the substrate W from a transfer means external to the heating unit 1000 and place the same on the heating plate 1310, or may lift the substrate W from the heating plate 1310 and hand over the same to the transfer means external to the heating unit 1000. In one example, three lift pins 1340 may be provided.

Therefore, when the substrate W is loaded on the lift pin 1340 raised by the lift pin driver 1341, the lift pin may be lowered by the lift pin driver 1341 so that the proximity pin 1370 supports the substrate W so as to be spaced from the heating plate 1310 in close proximity thereto. The heating plate 1310 may perform a baking process to harden a high-quality liquid film on the substrate W by repeatedly creating the humidifying and dehumidifying environments at least once.

As shown in FIG. 9, the gas spray hole 1121 may be formed in a position of the upper housing 1120 corresponding to an edge portion of the substrate W. The gas discharge hole 1122 may be formed in a center portion of the upper housing 1120 corresponding to a center portion of the substrate W so that the gas G1 or G2 may flow toward the center portion of the substrate W from the gas spray hole 1121 formed in the position of the upper housing 1120 corresponding to the edge portion of the substrate W.

The gas spray hole 1121 may include a vertical spray hole 1121a extending in a vertical direction toward the edge portion of the substrate W and an inclined spray hole 1121b extending inclinedly at an inclination angle K toward the center portion of the substrate W.

A portion of the first gas G1 or the second gas G2 introduced into the treatment space may be sprayed onto the edge portion of the substrate W through the vertical spray hole 1121a, while another portion of the first gas G1 or the second gas G2 may be sprayed toward the center portion of the substrate W through the inclined spray hole 1121b. Then, the portion of the first gas G1 or the second gas G2 flowing through the vertical spray hole 1121a and the portion of the first gas G1 or the second gas G2 flowing through the inclined spray hole 1121b may flow toward a center of the substrate W along the surface of the substrate W, and may merge with each other and then may be discharged to an outside through the gas discharge hole 1122.

An operation process of the substrate processing apparatus 1 according to some embodiments of the present disclosure will be described. First, as shown in FIG. 7, when the housing of the heating unit 1000 is in the open state, the second gas G2, that is, the inert gas such as nitrogen or argon, is supplied into the housing 1100, while the substrate W having the photoresist for extreme ultraviolet (EUV) coated thereon may be loaded into the treatment space of the housing 1100.

At this time, the ring shutter 1150 installed at the lower housing 1140 may be lowered to open the housing 1100, and the inert gas may be supplied to the heat-treatment chamber 3200 in FIG. 6 so that the inert gas environment is created around the housing 1100 so as to surround the housing 1100.

Next, as shown in FIG. 8, when the housing of the heating unit 1000 is in the closed state, the ring shutter 1150 installed in the lower housing 1140 is raised toward the upper housing 1120 to seal the housing 1100, and the humidified air as the first gas G1 may be supplied to the inside of the housing to create the humidifying environment on the substrate W.

At this time, the substrate W may be heated using the heating plate 1310 while supplying the inert gas to the inside of the housing 1100 to create the dehumidifying environment on the substrate W after the humidifying environment has been created. While the humidifying and dehumidifying environments may be repeatedly created at least once, the photoresist for extreme ultraviolet applied to the substrate W may be hardened into a high-quality liquid film.

Furthermore, in order to improve uniformity in gas flow, the humidified air or the inert gas may flow from the edge portion of the substrate W along the surface of the substrate W toward the center of the substrate W and then may merge thereat and may be discharged to the outside.

Afterwards, as shown in FIG. 7, The housing 1100 may be opened and the inert gas may be resupplied into the housing 1100. The treated substrate W may be unloaded from the housing 1100 to the outside.

Even at this time, the inert gas may be continuously supplied to the heat-treatment chamber 3200 in FIG. 6 so as to surround the housing 1100 to create the inert gas environment around the housing 1100 to prevent the liquid film on the treated substrate W from reacting with moisture.

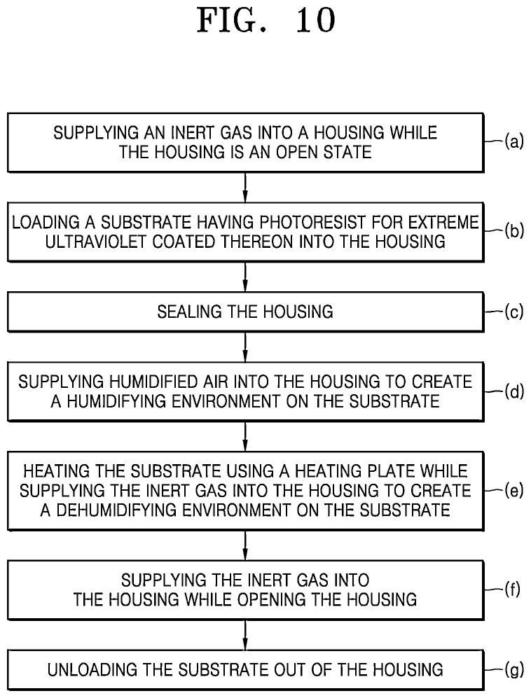

FIG. 10 is a flowchart showing a substrate treatment method according to some embodiments of the present disclosure.

As shown in FIGS. 1 to 10, the substrate treatment method according to some embodiments of the present disclosure may include (a) supplying the inert gas into the housing 1100 while the housing 1100 is in the open state; (b) loading the substrate W having the photoresist (PR) for extreme ultraviolet (EUV) coated thereon into the housing 1100; (c) sealing the housing 1100; (d) supplying humidified air to the inside of the housing 1100 to create the humidifying environment on the substrate W; (e) heating the substrate W using the heating plate 1310 while supplying the inert gas to the inside of the housing 1100 to create the dehumidifying environment on the substrate W; (f) supplying the inert gas into the housing 1100 while opening the housing 1100; and (g) unloading the substrate W out of the housing 1100.

After the step (e), the step (d) or the step (e) may be repeated at least once.

In the step (d), the humidified air may flow from the edge portion of the substrate W to the center portion of the substrate W using the gas spray hole 1121 corresponding to the edge portion of the substrate W and the gas discharge hole 1122 corresponding to the center portion of the substrate W.

In the step (e), the inert gas may flow from the edge portion of the substrate W to the center portion of the substrate W using the gas spray hole 1121 corresponding to the edge portion of the substrate W and the gas discharge hole 1122 corresponding to the center portion of the substrate W.

In the step (a), the housing 1100 may be opened by lowering the ring shutter 1150 installed at the lower housing 1140.

In the step (c), the ring shutter 1150 installed at the lower housing 1140 is raised toward the upper housing 1120 to seal the housing 1100.

Before the step (a), the method may further include of supplying the inert gas to the heat-treatment chamber 3200 so as to form a shape surrounding the housing 1100 so that the inert gas environment is created around the housing 1100.

Although the preferred embodiments of the present disclosure have been disclosed for illustrative purposes, those skilled in the art will appreciate that various modifications, additions and substitutions are possible, without departing from the scope and spirit of the disclosure as disclosed in the accompanying claims.

What is claimed is:

1. A substrate processing apparatus comprising:
a housing having a treatment space defined therein;
a support unit for supporting, thereon, a substrate received in the treatment space; and
a gas supply unit configured to alternately supply a first gas and a second gas into the treatment space in response to photoresist for extreme ultraviolet applied onto the substrate.

2. The substrate processing apparatus of claim 1, wherein the first gas is humidified air for providing a humidifying environment to the photoresist,
wherein the second gas is an inert gas for providing a dehumidifying environment or a surrounding moisture blocking environment to the photoresist.

3. The substrate processing apparatus of claim 2, wherein the gas supply unit includes:
a gas supply line installed in the housing so as to supply the humidified air or the inert gas;
a three-way valve having an output connected to the gas supply line;
a humidified air supply line connected to one input of the three-way valve; and
a first inert gas supply line connected to the other input of the three-way valve.

4. The substrate processing apparatus of claim 3, wherein the substrate processing apparatus further comprises a controller configured to:
apply a humidified air supply control signal for connecting the gas supply line and the humidified air supply line to each other during a humidification process; and
apply an inert gas supply control signal for connecting the gas supply line and the first inert gas supply line to each other during a dehumidification process or when blocking surrounding moisture.

5. The substrate processing apparatus of claim 3, wherein a heater is installed in the humidified air supply line so as to prevent condensation of the humidified air.

6. The substrate processing apparatus of claim 1, wherein the housing includes:
an upper housing having at least one gas spray hole defined therein for spraying the first gas or the second gas toward the substrate and a gas discharge hole defined therein for discharging the sprayed gas to an outside;
a lower housing spaced apart from the upper housing so that the treatment space is defined therebetween, wherein the support unit is installed on an inner upper surface of the lower housing; and
a ring shutter installed at the lower housing or the upper housing and configured to vertically move to block a space defined between the upper housing and the lower housing to seal the treatment space.

7. The substrate processing apparatus of claim 6, wherein the at least one gas spray hole includes:
a vertical spray hole extending in a vertical direction toward an edge portion of the substrate; and
an inclined spray hole extending inclinedly toward a center portion of the substrate.

8. The substrate processing apparatus of claim 7, wherein the gas discharge hole is formed in a center portion of the upper housing corresponding to the center portion of the substrate so that the gas flows from the edge portion of the substrate to the center portion of the substrate.

9. The substrate processing apparatus of claim 6, wherein the housing further includes a sealing member installed on a lower surface of the upper housing or an upper surface of the lower housing to prevent inflow of external air into the treatment space.

10. The substrate processing apparatus of claim 6, wherein the housing further includes a ring shutter vertically-moving unit for moving the ring shutter vertically.

11. The substrate processing apparatus of claim 1, wherein the support unit includes:
a heating plate having a heater built therein to heat the substrate;
a lift pin installed at the heating plate so as to vertically move the substrate in loading and unloading the substrate; and
a proximity pin installed on the heating plate so as to support the substrate thereon such that the substrate is spaced from the heating plate in proximity thereto when the lift pin descends.

12. The substrate processing apparatus of claim 1, wherein the substrate processing apparatus further comprises:
a heat-treatment chamber;
a cooling unit installed in the heat-treatment chamber so as to cool the substrate; and
a heating unit installed in the heat-treatment chamber so as to heat the substrate,
wherein the heating unit includes the housing, the support unit, and the gas supply unit,
wherein the heat-treatment chamber includes:
a chamber body having a substrate passage defined at one side thereof;
a gate valve for blocking the substrate passage; and
a second inert gas supply line installed in the heat-treatment chamber so as to supply an inert gas into the heat-treatment chamber.

13. A substrate processing method comprising:
(a) supplying an inert gas into a housing while the housing is an open state;
(b) loading a substrate having photoresist for extreme ultraviolet coated thereon into the housing;
(c) sealing the housing;
(d) supplying humidified air into the housing to create a humidifying environment on the substrate;
(e) heating the substrate using a heating plate while supplying the inert gas into the housing to create a dehumidifying environment on the substrate;
(f) supplying the inert gas into the housing while opening the housing; and
(g) unloading the substrate out of the housing.

14. The substrate processing method of claim 13, wherein after the (e), the (d) or the (e) is repeated at least once.

15. The substrate processing method of claim 13, wherein in the (d), the humidified air flows from an edge portion of the substrate to a center portion of the substrate using a gas spray hole corresponding to the edge portion of the substrate and a gas discharge hole corresponding to the center portion of the substrate.

16. The substrate processing method of claim 13, wherein in the (e), the inert gas flows from an edge portion of the substrate to a center portion of the substrate using a gas spray hole corresponding to the edge portion of the substrate and a gas discharge hole corresponding to the center portion of the substrate.

17. The substrate processing method of claim 13, wherein in the (a), the housing is opened by lowering a ring shutter installed at a lower housing, wherein the housing includes an upper housing and the lower housing.

18. The substrate processing method of claim 17, wherein in the (c), the ring shutter installed at the lower housing is raised up toward the upper housing to seal the housing.

19. The substrate processing method of claim 13, wherein the method further comprises, before the (a),
(h) supplying the inert gas into a heat-treatment chamber so as to form a shape surrounding the housing so that an inert gas environment is created around the housing.

20. A substrate processing apparatus comprising:
a heat-treatment chamber;
a cooling unit installed in the heat-treatment chamber so as to cool a substrate; and
a heating unit installed in the heat-treatment chamber so as to heat the substrate,
wherein the heating unit includes:
a housing having a treatment space defined therein;
a support unit for supporting, thereon, the substrate received in the treatment space; and
a gas supply unit configured to alternately supply a first gas and a second gas into the treatment space in response to photoresist for extreme ultraviolet applied onto the substrate,
wherein the heat-treatment chamber includes:
a chamber body having a substrate passage defined at one side thereof;
a gate valve for blocking the substrate passage; and
a second inert gas supply line installed in the heat-treatment chamber so as to supply an inert gas into the heat-treatment chamber,
wherein the first gas is humidified air for providing a humidifying environment to the photoresist,
wherein the second gas is an inert gas for providing a dehumidifying environment or a surrounding moisture blocking environment to the photoresist,
wherein the gas supply unit includes:
a gas supply line installed in the housing so as to supply the humidified air or the inert gas;
a three-way valve having an output connected to the gas supply line;
a humidified air supply line connected to one input of the three-way valve; and
a first inert gas supply line connected to the other input of the three-way valve,
wherein the substrate processing apparatus further comprises a controller configured to:
apply a humidified air supply control signal for connecting the gas supply line and the humidified air supply line to each other to the three-way valve during a humidification process; and
apply an inert gas supply control signal for connecting the gas supply line and the first inert gas supply line to each other to the three-way valve during a dehumidification process or when blocking surrounding moisture,
wherein a heater is installed in the humidified air supply line so as to prevent condensation of the humidified air,
wherein the housing includes:
an upper housing having at least one gas spray hole defined therein for spraying the first gas or the second gas toward the substrate and a gas discharge hole defined therein for discharging the sprayed gas to an outside;
a lower housing spaced apart from the upper housing so that the treatment space is defined therebetween, wherein the support unit is installed on an inner upper surface of the lower housing; and
a ring shutter installed at the lower housing or the upper housing and configured to vertically move to block a space defined between the upper housing and the lower housing to seal the treatment space,
wherein the at least one gas spray hole includes:
a vertical spray hole extending in a vertical direction toward an edge portion of the substrate; and
an inclined spray hole extending inclinedly toward a center portion of the substrate,
wherein the gas discharge hole is formed in a center portion of the upper housing corresponding to the center portion of the substrate so that the gas flows from the edge portion of the substrate to the center portion of the substrate.
